(19) United States
(12) Patent Application Publication
(10) Pub. No.: US 2003/0112073 A1
(43) Pub. Date: Jun. 19, 2003

(54) RF amplifier with current mirror bias-boosting

(75) Inventors: Sifen Luo, Hartsdale, NY (US); Tirdad Sowlati, Ossining, NY (US)

Correspondence Address: PHILIPS ELECTRONICS NORTH AMERICAN CORP, 580 WHITE PLAINS RD, TARRYTOWN, NY, 10591, US

(73) Assignee: KONINKLIJKE PHILIPS ELECTRONICS N.V.

(21) Appl. No.: 10/022,123

(22) Filed: Dec. 13, 2001

(51) Int. Cl. H03G 3/10

(52) U.S. Cl. 330/285

(57) ABSTRACT

An amplifier circuit comprises an input stage and an output stage. The input stage is biased by means of a circuit, such as a current mirror, that senses the input signal level. As the input signal increases the average current of the sensing circuit also increases. This current is fed forward to the output stage to boost its bias.

The bias boosting is thus proportional to the input signal. One of the advantages of the bias scheme presented is that it allows amplifiers to be biased with a lower quiescent current without being pushed into saturation at higher output power levels.

### TECHNICAL FIELD

The present invention relates to power amplifiers, and more specifically, to an improved bias boosting technique for power amplifiers suitable for use in high frequency applications.

### BACKGROUND OF THE INVENTION

A linear RF power amplifier is commonly biased in class AB operation so as to achieve higher power-added efficiency. Such an amplifier is commonly used in the output stage of high-frequency power amplifiers. However, in a conventionally biased class AB amplifier, the average bias supply current increases as RF input power increases. This increased average current results in an increased voltage drop in the resistive part of the bias circuit. This in turn reduces the average voltage drop across the forward-biased PN junction of the power amplifying transistor, pushing the amplifier into class B and even class C operations. Therefore, the output power will be saturated as the input power further increases.

Class AB amplifiers are commonly used in high-frequency amplifiers. Linear RF amplifiers are usually biased in a class AB operation to achieve higher power-added efficiency (“PAE”).

In a conventionally biased class AB amplifier, as radio frequency (“RF”) input power increases, the average bias supply-current increases. This increased average direct current (“DC”) results in an increased voltage drop in the resistive part of the bias circuit. This increased voltage drop across the biasing resistor, in turn, reduces the voltage drop across the forward-biased PN junction of the amplifying transistor, thereby saturating its large signal transconductance and reducing its gain. Thus, as RF input power increases, the amplifier may be pushed into class B operations (in which conduction takes place during 50% of the signal cycle) or class C operations (conduction takes place during less than 50% of the signal cycle). As input power further increases, output power saturation will occur.

Boosting of the DC bias of the amplifying transistor is necessary to compensate for the aforementioned DC drop. This DC bias increase will improve linearity at higher output power levels where the class AB amplifier is in saturation or close to saturation levels, as described above. Existing techniques for providing such bias boosting have utilized two approaches. One such technique involves using a capacitor together with a biasing circuit consisting of two or more transistors. Another such technique involves using an additional RF sensing amplifier. These techniques are the subject of other recent inventions commonly owned with this patent application, and thus do not constitute prior art.

In the former technique, the bias boosting relies on the value of the capacitor. If an on-chip capacitor is used, it is relatively difficult to control its capacitance value. If an off-chip capacitor is used, it increases the number of off-chip components, thereby requiring additional valuable space, or “real estate”, on the printed circuit board (“PCB”).

In the latter technique, the additional RF sensing amplifier may increase the chip area of the circuit.

In view of the above, there exists a need in the art for an improved power amplifier configuration which increases the amplifier's gain, PAE and linearity, yet does not significantly increase the chip area of the amplifier circuit or the number of off-chip components.

It is therefore an object of the present invention to provide an amplifier circuit that boosts the bias of the output stage without significantly increasing the chip area of the circuit or of the PCB comprising the circuit.

It is a further object of the present invention to provide a power amplifier circuit that permits biasing with a lower quiescent current without having a saturation effect at higher output power levels.

### SUMMARY OF THE INVENTION

An amplifier circuit comprises an input stage and an output stage. The input stage is biased by means of a circuit, such as a current mirror, that senses the input signal level. As the input signal increases the average current of the sensing circuit also increases. This current is fed forward to the output stage biasing circuit to boost its bias.

The bias boosting is thus proportional to the input signal. One of the advantages of the bias scheme presented is that it allows amplifiers to be biased with a lower quiescent current without being pushed into saturation at higher output power levels.

### BRIEF DESCRIPTION OF THE DRAWINGS

The present invention may be more clearly understood with reference to the following description, to be read in conjunction with the accompanying drawings:

FIG. 1 depicts an RF power amplifier according to the method of the present invention;

FIG. 1A is a simplified version of a portion of the circuit of FIG. 1, highlighting the novel components;

FIG. 2 depicts an RF power amplifier according to the conventional biasing scheme; and

FIG. 3 depicts an existing bias circuit technique using two current sources.

### DETAILED DESCRIPTION OF THE DRAWINGS

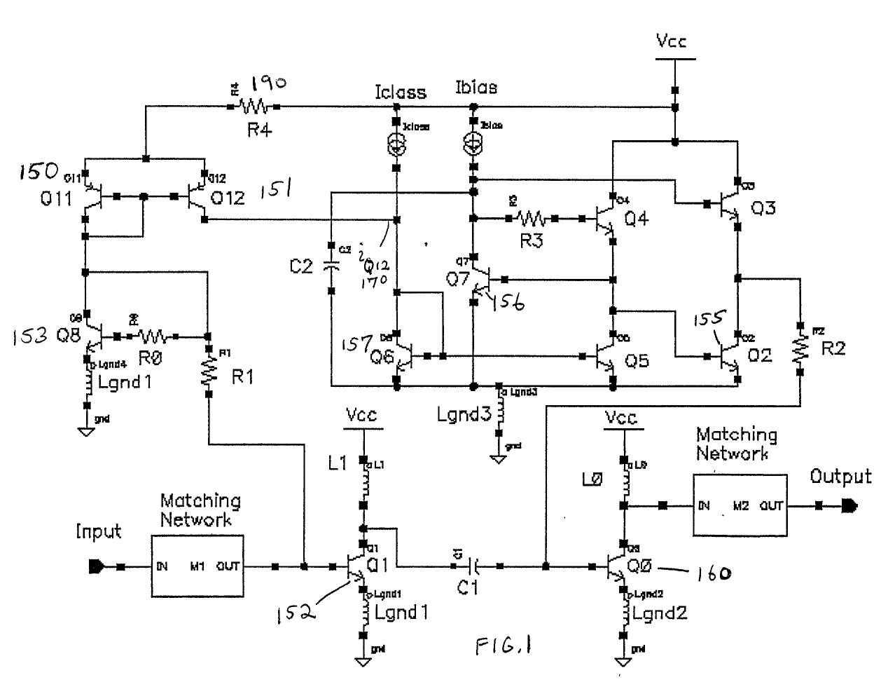

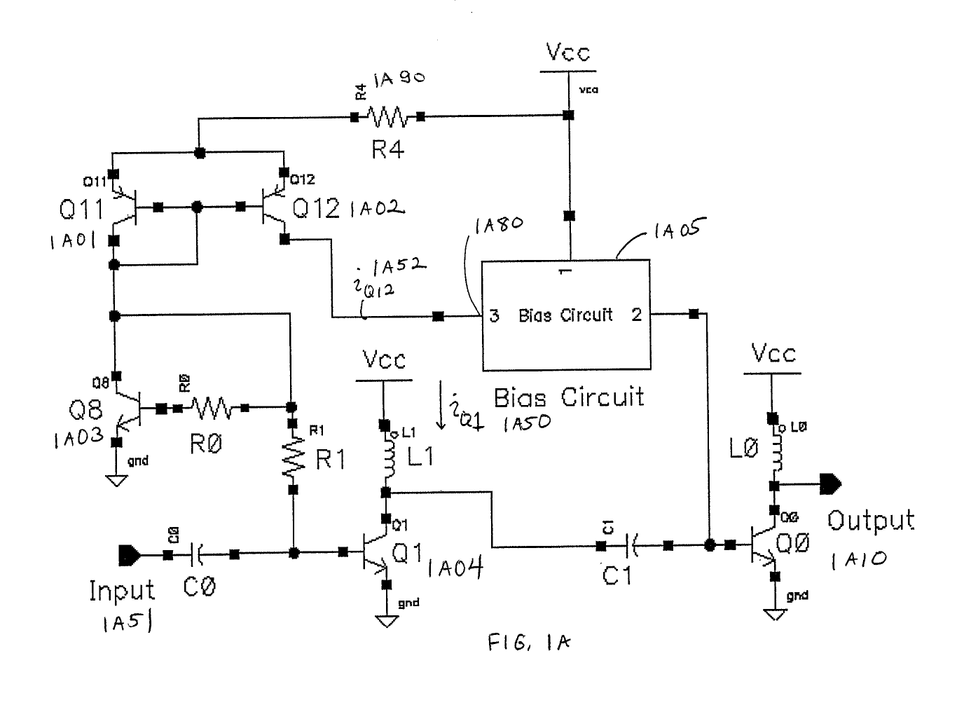

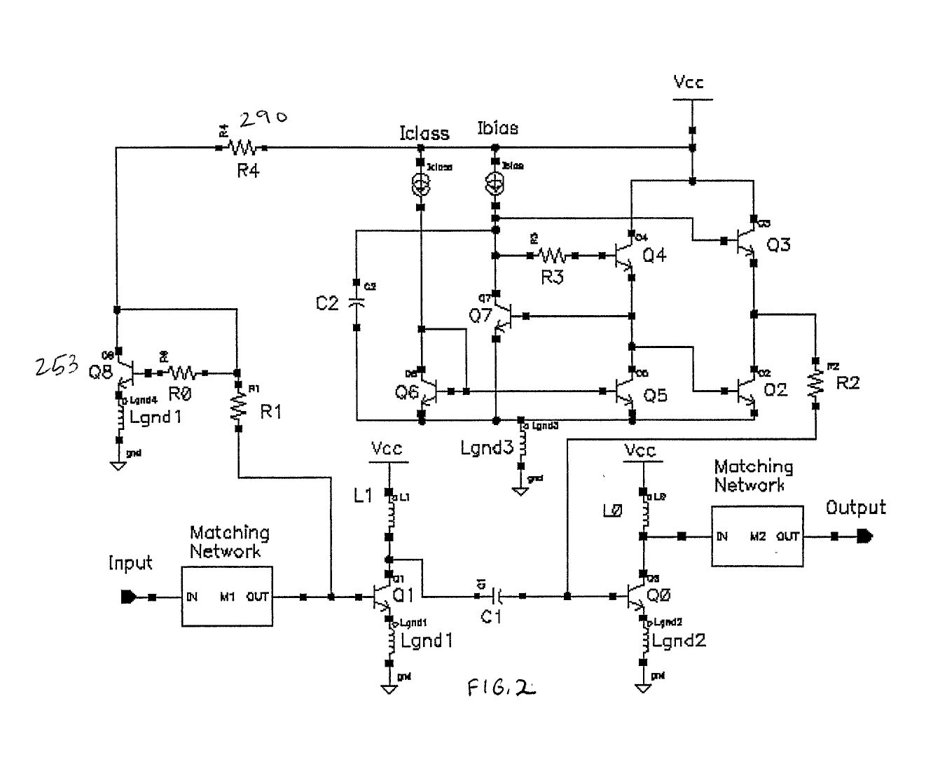

FIG. 1 shows an exemplary RF power amplifier configuration, incorporating the novel bias boosting scheme of the present invention. As a comparison, FIG. 2 depicts a schematic of a conventional RF power amplifier, without the added bias boosting scheme. These two circuits are almost identical, with the exception of the additional current mirror circuit consisting of transistors Q11 150 and Q12 151, at the top left of the figure, in FIG. 1.

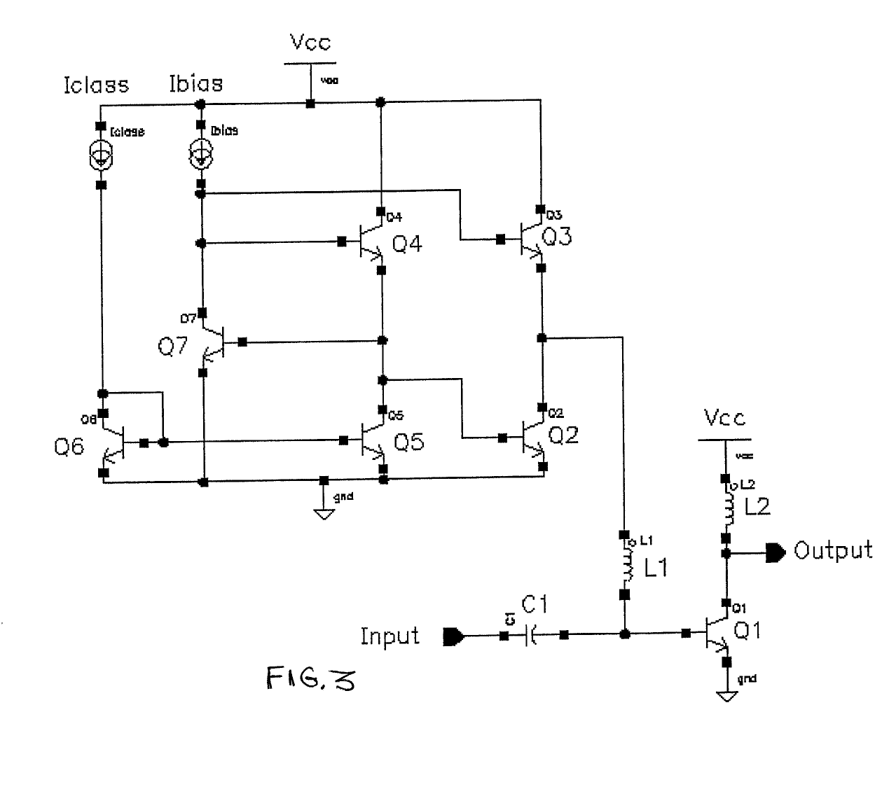

In these circuits, transistors Q1 152 and Q8 153 have been matched to form a current mirror circuit. Q2 155 through Q7 156 form a biasing circuit for the output stage, which is transistor Q0 160. The biasing circuit technique is shown generally at FIG. 3. Such biasing technique is the subject of another recent invention commonly owned with this patent application and thus does not constitute prior art.

For ease of description FIG. 1A will be used to describe the method of the present invention in detail. FIG. 1A is a simplified version of the portion of the circuit of FIG. 1 critical to the present invention. FIG. 1A depicts the novel current mirror, the input stage biasing circuit, and the output stage. The output stage biasing circuit, which comprises transistors Q2 155 through Q7 156 in FIG. 1, is simplified in FIG. 1A to a circuit block 1A05.

When Q1 A04 is biased in a class AB operation, its average collector current iQ1 1A50 will increase as the RF input signal level 1A51 increases, which is a typical characteristic for class AB or class B amplifiers. Since Q1 A04 and Q8 1A03 form a current mirror circuit, the current in Q1 1A04 is mirrored in Q8 1A03. Because the identical current flows in Q8 as in Q11 1A01, as they are connected in series, this current is mirrored by the current mirror circuit consisting of transistors Q11 1A01 and Q12 1A02 into Q12 as iQ12 1A52, and thus is fed to the output stage bias circuit 1A05, entering through port 3, 1A80. The biasing circuit controls the quiescent current in Q0 1A10. With reference to FIG. 1, iQ12 170 is fed into Q6 157. Consequently, the current in Q6 provides a bias boost for Q0, the amplifying transistor.

Therefore, the addition of the current mirror of Q11 and Q12 permits an added bias boost for Q0. In a linear RF amplifier whose input stage biased in a class AB mode, this configuration increases the output stage biasing level in proportion to higher input signal levels; thereby improving linearity (reduced gain compression) at higher output power levels. Inasmuch as the method of the present invention increases the bias boost proportionally to the input RF signal level, it is in fact, an adaptive bias-boosting scheme.

The placing of the current mirror is flexible vis-a-vis that of R4 290 (with respect to FIG. 2). R4 operates to control the DC current through Q8 253, and is thus a type of biasing resistor. The current mirror of the present invention may be placed below biasing resistor R4 (190 in FIG. 1 and 1A90 in FIG. 1A), as depicted in the example circuits of FIGS. 1 and 1A, or above it, with R4 in series between transistors Q11 150, 1A50 and Q8 153, 1A53 (this latter possible placement of R4 is not shown in the figures). This flexibility allows the choice of the most advantageous placing as will depend upon the particular design considerations of a given circuit embodying the method of the present invention.

Simulation results indicate that the bias boosting scheme of the present invention provides benefits to the amplifier in terms of gain, PAE and linearity due to reduced gain compression. Additionally, it allows RF amplifiers to be biased with a lower quiescent current, without pushing it into saturation at higher output power levels.

In another embodiment, if further boosting is needed, a self-bias boost scheme can be used in combination with the current mirror technique of the present invention. An example of just such a self bias boost scheme, is one that which utilizes a capacitor together with a bias circuit, as discussed above.

It is anticipated by the invention that the input as well as output biasing circuits may comprise other types of current mirror circuits, in addition to the circuit described above, or other means of generating a reference current in one part of a circuit and generating proportional currents at other locations in the circuit. Further contemplated by the invention are any means which adaptively boost an amplification circuit or subcircuit by sensing an input signal and boosting the output stage bias in proportion to such input signal.

It is understood that while the foregoing describes the preferred embodiments of the invention, various other modifications and additions will be apparent to those of skill in the art. For example, this bias boosting scheme should not be limited to circuits using bipolar junction transistors (“BJTs”), as described in the above preferred embodiment. Circuits using other amplification devices such as field effect transistors (“FETs”) or derivatives of BJTs or FETS, such as the metal oxide semiconductor field effect transistor (“MOSFET”), may also fall within the scope of the present invention. The invention also covers circuits using both FETs and BJTs, or other amplifier configurations as are known, or may be known in the future, in the art. In addition, alterations to the circuit configuration may be made to suit particular design requirements.

What is claimed:

1. A method for improving the performance of an amplifier circuit comprising:
sensing the current in the input stage;
feeding said current to the output stage bias circuit to boost the output bias.

2. The method of claim 1, wherein the current is sensed and fed to the output stage bias circuit via a current mirror.

3. The method of claim 2, where the current at the entry terminal of the input stage transistor is the mirrored current.

4. The method of any of claims 1-3, wherein the circuit comprises BJTs.

5. The method of any of claims 1-3, wherein the circuit comprises FETs.

6. The method of any of claims 1-3, wherein the circuit comprises a combination of BJTs and FETs.

7. A transistor circuit, comprising:
an input stage;
an output stage with a biasing circuit; and
a current mirror, which senses the input signal current and
feeds it to the output stage biasing circuit.

8. The circuit of claim 7, where the circuit comprises BJTs.

9. The circuit of claim 7, where the circuit comprises FETs.

10. The circuit of claim 7, where the circuit comprises a combination of BJTs and FETs.

11. A method of adaptively boosting the bias of an amplifier circuit, comprising:
sensing the input signal; and
boosting the output stage bias with a current equal or proportional to the input signal.

12. The method of claim 11, where the input signal is an RF signal.

13. The method of claim 12, where the input signal is sensed by a current mirror biasing circuit for the input stage.

14. The method of claim 13, where the collector current of an input stage BJT is mirrored by the current mirror and fed into an output stage biasing circuit.

15. The method of claim 13, where the drain current of an input stage FET is mirrored by the current mirror and fed into an output stage biasing circuit.

16. The method of any of claims 13-15, where the current mirror comprises BJTs.

17. The method of any of claims 13-15, where the current mirror comprises FETs.

18. A subcircuit, to be used in an amplification circuit, comprising:
an input sensor, arranged to sense the input signal to the circuit; and
an output stage booster, arranged to boost the bias of an output stage of the circuit in proportion to said input signal.

19. The subcircuit of claim 18, where the input signal is an RF signal.

20. The subcircuit of either of claims 18 or 19, where the input sensor is a current mirror.
